(19) United States
(12) Patent Application Publication
(10) Pub. No.: US 2013/0017626 A1
(43) Pub. Date: Jan. 17, 2013

(54) ETCHING APPARATUS AND METHOD OF MANUFACTURING SEMICONDUCTOR DEVICE

(71) Applicant: Kazuhiro TOMIOKA, Yokohama-shi (JP)

(72) Inventor: Kazuhiro TOMIOKA, Yokohama-shi (JP)

(21) Appl. No.: 13/425,848

(22) Filed: Mar. 21, 2012

(30) Foreign Application Priority Data
Jul. 11, 2011 (JP) 2011-153218

(51) Int. Cl. H01L 21/302; H01L 21/3065

(52) U.S. Cl. 438/3; 438/710; 156/345.26; 257/E21.214

(57) ABSTRACT

According to one embodiment, an etching apparatus includes a stage having an upper surface and a lower surface, and being capable of mounting a substrate on the upper surface, a chamber covering above the upper surface, a lower electrode having an opening portion, and provided under the lower surface, a gas supplying portion supplying an etching gas in the chamber, a high-frequency power source portion executing a plasma gasification of the etching gas by applying a high-frequency to the lower electrode, a micro wave generating portion setting a temperature of the substrate within an optimum range by applying a micro wave to the substrate through the opening portion, and a control portion controlling the gas supplying portion, the high-frequency power source portion and the micro wave generating portion.

### CROSS-REFERENCE TO RELATED APPLICATIONS

This application is based upon and claims the benefit of priority from prior Japanese Patent Application No. 2011-153218, filed Jul. 11, 2011, the entire contents of which are incorporated herein by reference.

### FIELD

Embodiments described herein relate generally to an etching apparatus and a method of manufacturing a semiconductor device.

### BACKGROUND

Recently, a method of manufacturing a semiconductor device must inevitably perform a process of etching a so-called etching resistant material (e.g., a precious metal, ferroelectric material, or ferromagnetic material) having poor reactivity to an etching gas and a low vapor pressure of a reaction product. This boosts demand for developing a technique of etching an etching resistant material at a high speed and high precision with small damage.

### BRIEF DESCRIPTION OF THE DRAWINGS

FIG. 1 is a view showing an etching apparatus;

FIGS. 2 and 3 are views each showing a lower electrode;

FIG. 4 is a graph for explaining an optimum temperature in etching;

FIG. 5 is a graph showing a comparison between microwave heating and heater heating;

FIGS. 6, 7, and 8 are flowcharts each showing an etching method;

FIGS. 9 and 10 are views showing the first example of a method of manufacturing a semiconductor device;

FIGS. 11, 12, 13, 14, and 15 are views showing the second example of the method of manufacturing a semiconductor device;

FIG. 16 is a view showing the memory cell array of an MRAM; and

FIG. 17 is a view showing the memory cell of the MRAM.

### DETAILED DESCRIPTION

In general, according to one embodiment, an etching apparatus comprising: a stage having an upper surface and a lower surface, and being capable of mounting a substrate on the upper surface; a chamber covering above the upper surface; a lower electrode having an opening portion, and provided under the lower surface; a gas supplying portion supplying an etching gas in the chamber; a high-frequency power source portion executing a plasma gasification of the etching gas by applying a high-frequency to the lower electrode; a micro wave generating portion setting a temperature of the substrate within an optimum range by applying a micro wave to the substrate through the opening portion; and a control portion controlling the gas supplying portion, the high-frequency power source portion and the micro wave generating portion.

An embodiment will now be described with reference to the drawings.

### (1) ETCHING APPARATUS

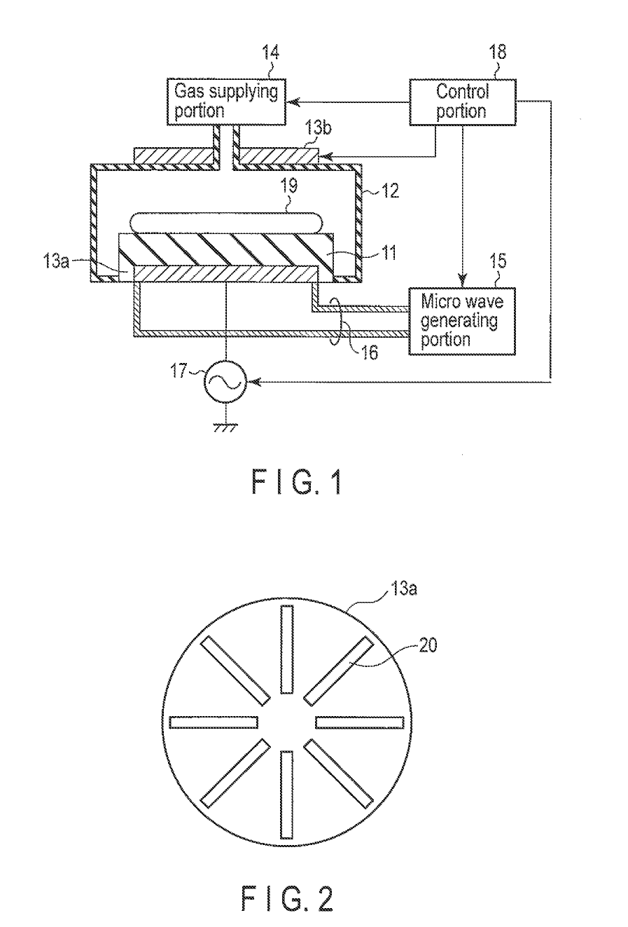

FIG. 1 shows an etching apparatus.

This etching apparatus includes stage (e.g., ceramic plate) 11, chamber 12, lower electrode 13a, upper electrode 13b, gas supplying portion 14, microwave generating portion 15, waveguide 16, high-frequency power source portion 17, and control portion 18.

Substrate (e.g., wafer) 19 is mounted on stage 11. Gas supplying portion 14 supplies an etching gas such as a halogen gas or halogen compound gas into vacuum chamber 12.

High-frequency power source portion 17 applies a high-frequency to lower electrode 13a. Then, a plasma gasification of the etching gas in chamber 12 is executed, and ions are accelerated toward substrate 19 by bias power. Upper electrode 13b is, e.g., a coil.

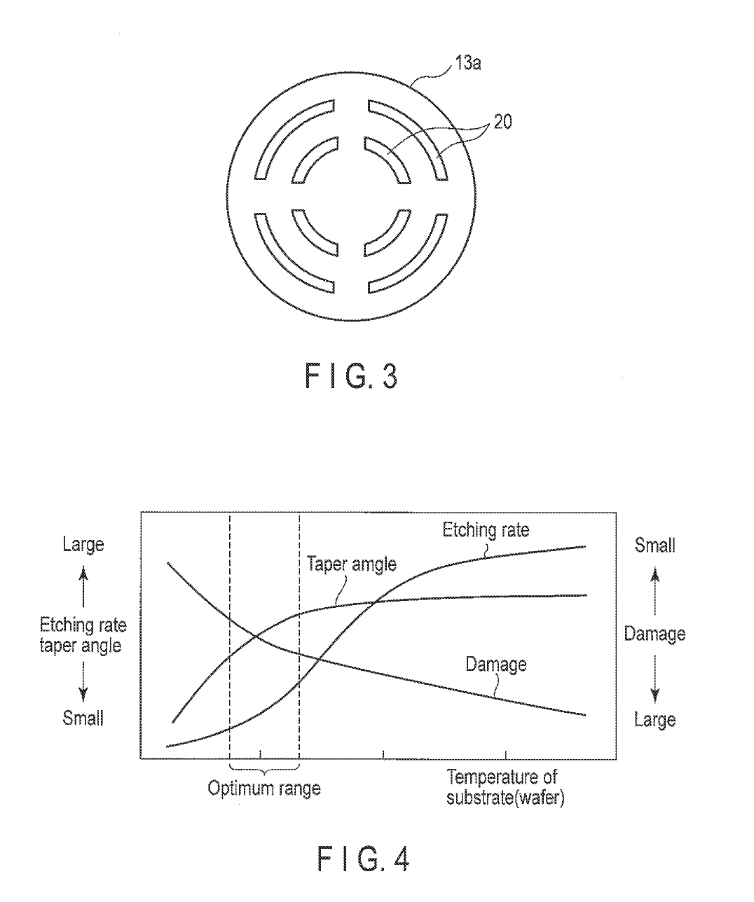

As shown in FIGS. 2 and 3, lower electrode 13a has opening portions 20. The shape of opening portion 20 is not particularly limited. It is desirable to uniformly arrange opening portions 20 in lower electrode 13a.

Microwave generating portion 15 generates a microwave (e.g., 1 to 10 GHz) to directly heat substrate 19. The microwave is applied to substrate 19 through waveguide 16 and opening portions 20 (see FIGS. 2 and 3) formed in lower electrode 13a.

When etching substrate 19, control portion 18 controls the operations of gas supplying portion 14, microwave generating portion 15, and high-frequency power source portion 17.

A feature of the etching apparatus is that microwave generating portion 15 is arranged to generate a microwave for directly heating substrate 19. This heating means heating of entire substrate 19. With microwave generating portion 15, the temperature of substrate 19 can be set to a predetermined value quickly in etching.

The microwave is applied to substrate 19 through the opening portions formed in lower electrode 13a and heats substrate 19. More specifically, the microwave is applied from the lower surface (surface opposite to the etching surface) of substrate 19. The temperature of substrate 19 can be set to a predetermined value quickly by a simple arrangement without complicating the etching apparatus.

### (2) TEMPERATURE OF SUBSTRATE

Recently, a process of etching an etching resistant material (e.g., a precious metal, ferroelectric material, or ferromagnetic material) is essential to a method of manufacturing a semiconductor device.

For example, a DRAM (Dynamic Random Access Memory) has a capacitor structure in which an oxide-containing dielectric material such as Si, Ta, Zr, Y, or La is sandwiched between layers of a precious metal such as Pt, Ir, or Ru. An FeRAM (Ferroelectric Random Access Memory) has a capacitor structure in which a ferroelectric material such as PZT is sandwiched between layers of a precious metal such as Pt, Ir, or Ru.

Further, an MRAM (Magnetic Random Access Memory) has a stacked structure in which a ferromagnetic material including Co, Fe, Ni, ir, Pt, Mn, or Ru is sandwiched between layers of a precious metal such as Pt, It, or Ru.

In this manner, the capacitor structures of the DRAM and FeRAM and the stacked structure of the MRAM include etching resistant materials. It is needed to develop a technique of etching these materials at a high speed and high precision with small damage.

An important factor to etch the etching resistant material at a high speed and high precision with small damage is the temperature of a wafer serving as a substrate.

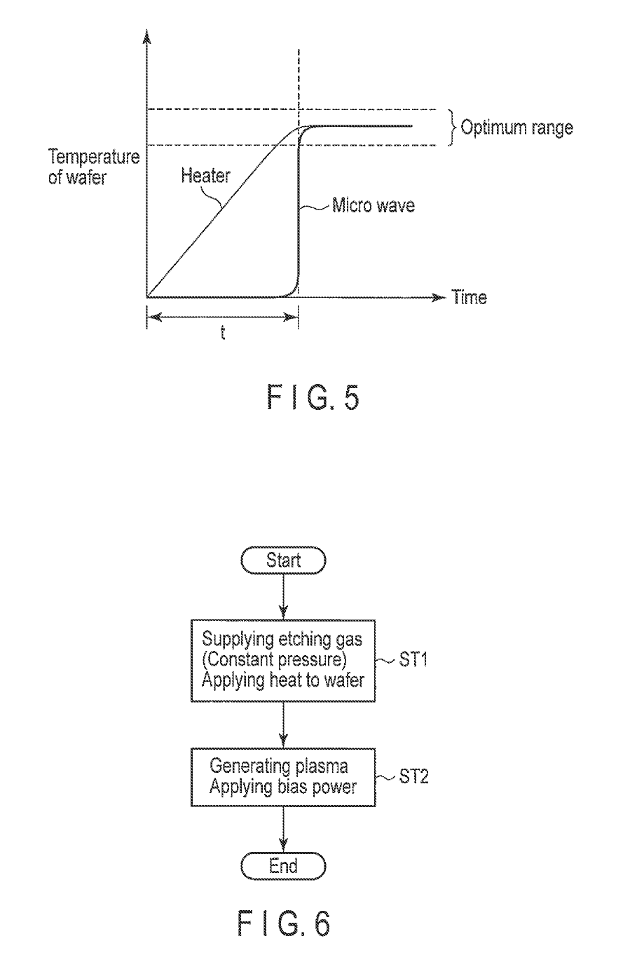

FIG. 4 shows the relationship between the wafer temperature and the etching rate/taper angle/damage.

In etching of the etching resistant material, the etching rate and taper angle increase as the wafer temperature rises. Note that the taper angle is the angle of the etching resistant material with respect to the upper surface of an underlayer, and the maximum value is 90°.

This is because, as the wafer temperature rises, the vapor pressure of a reaction product also rises. A high vapor pressure of the reaction product increases the etching rate and the selectivity to the mask, and decreases the re-deposition. A high selectivity to the mask suppresses retraction of the mask (size reduction by etching) to prevent etching inhibition caused by the re-deposition, thus increasing the taper angle.

A high etching rate enables etching an etching resistant material at a high speed. A large taper angle enables etching an etching resistant material at high precision. To implement a high speed and high precision, it is desirable to maximize the wafer temperature.

However, as the wafer temperature rises, damage to the etching resistant material becomes larger. In semiconductor devices such as the DRAM, FeRAM, and MRAM mentioned above, as the wafer temperature rises, the capacitor, stacked structure, and the like are more readily damaged, impairing the element characteristics.

In this way, as for etching of an etching resistant material, the etching rate/taper angle and the damage have a trade-off relationship.

In etching of an etching resistant material, the optimum range of the wafer temperature is set in consideration of these three factors.

For example, for an etching resistant material (e.g., ferromagnetic material) used in the MRAM, the optimum range is as narrow as 200° C. to 350° C., and more desirably 250° C. to 275° C. For an etching resistant material (e.g., ferroelectric material) used in the FeRAM, the optimum range is as narrow as 250° C. to 400° C., and more desirably 300° C. to 350° C.

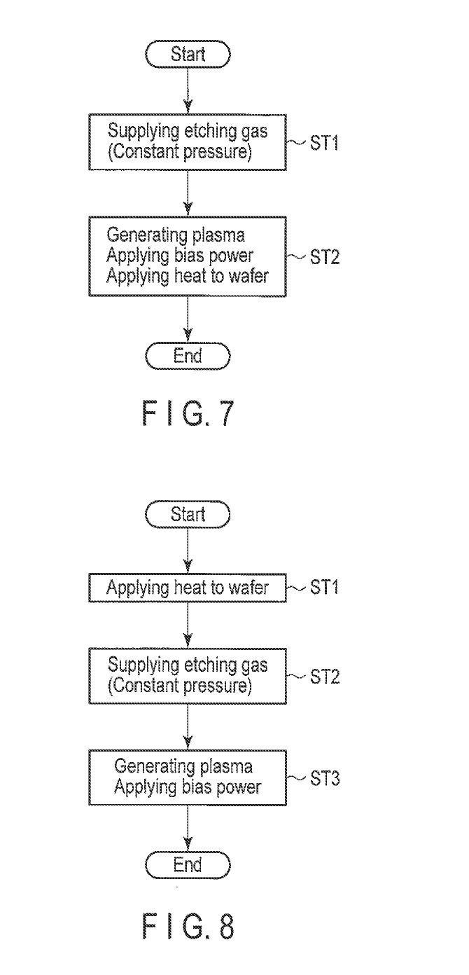

In general, a conventional etching apparatus heats a wafer by using a heater. However, as shown in FIG. 5, heating by the heater takes a long time t to set the wafer temperature within an optimum range. Also, it is difficult to maintain the temperature within the optimum range by the heater.

Further, there is proposed a method of setting the wafer temperature within the optimum range in advance. However, in this method, the wafer needs to be kept at a high temperature for a long time, so the etching resistant material is damaged seriously.

To prevent this, according to the embodiment, the etching apparatus shown in FIG. 1 is used to directly heat a wafer by a microwave and set the wafer temperature within the optimum range quickly. For example, heating by the microwave has a feature capable of setting the wafer temperature within the optimum range quickly, as shown in FIG. 5.

Note that heating by the microwave (e.g., microwave annealing) has conventionally been known. However, this method is free from a problem generated only in etching an etching resistant material, that is, a problem in which the wafer temperature in etching needs to be maintained within the optimum range while taking account of a trade-off between the etching rate/taper angle and the damage.

Therefore, an etching apparatus and a method of manufacturing a semiconductor device according to the embodiment cannot be easily anticipated from well-known microwave heating techniques.

### (3) OPERATION (ETCHING METHOD)

The operation (etching method) of the etching apparatus in FIG. 1 will be explained.

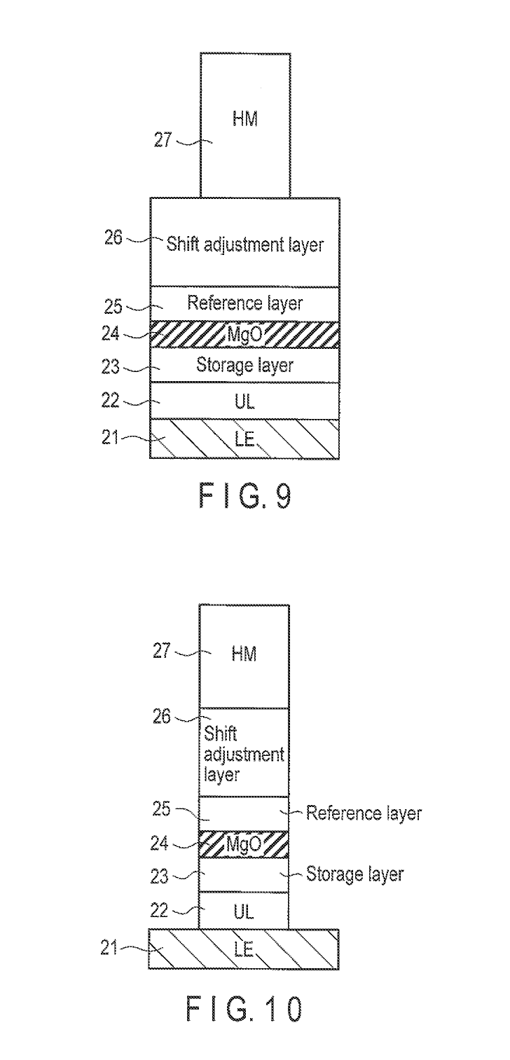

FIG. 6 shows the first example of the operation of the etching apparatus.

Control portion 18 of the etching apparatus in FIG. 1 controls this operation.

First, wafer 19 is placed on stage 11. In this state, gas supplying portion 14 supplies an etching gas in vacuum chamber 12. At this time, the pressure in chamber 12 is kept constant. Simultaneously when supplying the etching gas, microwave generating portion 15 generates a microwave, setting the temperature of wafer 19 within an optimum range (step ST1).

Then, a plasma gasification of the etching gas is executed by applying a high-frequency power from high frequency power source portion 17 to lower electrode 13a in a state of setting the temperature of wafer 19 within the optimum range. In addition, plasma ions are accelerated toward wafer 19 by bias power, etching wafer 19 (step ST2).

In this operation, heating of wafer 19 by the microwave is executed in parallel to supplying the etching gas.

FIG. 7 shows the second example of the operation of the etching apparatus.

Control portion 18 of the etching apparatus in FIG. 1 also controls this operation.

First, wafer 19 is placed on stage 11. In this state, gas supplying portion 14 supplies an etching gas in vacuum chamber 12. At this time, the pressure in chamber 12 is kept constant.

Then, a plasma gasification of the etching gas is executed by applying a high-frequency from high-frequency power source portion 17 to lower electrode 13a in a state of setting the temperature of wafer 19 within an optimum range. In addition, plasma ions are accelerated toward wafer 19 by bias power, etching wafer 19.

At the same time, microwave generating portion 15 generates a microwave, setting the temperature of wafer 19 within the optimum range (step ST1).

In this operation, heating of wafer 19 by the microwave is executed in parallel to generating a plasma/applying bias power.

In either example, the temperature of wafer 19 can be set within the optimum range quickly. Etching of an etching resistant material at a high speed and high precision with small damage can be implemented.

In contrast, the operation (comparative example) of an etching apparatus which heats a wafer by using a heater is as shown in the flowchart of FIG. 8.

First, a wafer is heated in advance (step ST1).

This is because heating by the heater takes time to set the wafer temperature within an optimum range.

Then, the gas supplying portion supplies an etching gas in the vacuum chamber in a state of setting the wafer temperature within an optimum range. At this time, the pressure in the chamber is kept constant (step ST2).

A plasma gasification of the etching gas is executed by applying a high-frequency from the high-frequency power source portion to the lower electrode in a state of setting the wafer temperature within the optimum range. Further, plasma ions are accelerated toward the wafer by bias power, etching the wafer (step ST3).

This comparative example additionally requires the step of setting a wafer within an optimum range in advance. Hence, the throughput drops, and the etching resistant material is damaged.

### (4) METHOD OF MANUFACTURING SEMICONDUCTOR DEVICE

In a method of manufacturing a semiconductor device having a stacked structure including an etching resistant material (e.g., a precious metal, ferroelectric material, or ferromagnetic material), the etching apparatus in FIG. 1 can be used to etch the stacked structure by a plasma etching in a state of setting the stacked structure at a temperature within an optimum range by a microwave. Thus, the etching resistant material can be etched at a high speed (high throughput) and high precision (high shape controllability) without damaging the etching resistant material.

An MRAM will be exemplified for the method of manufacturing a semiconductor device having a stacked structure including an etching resistant material.

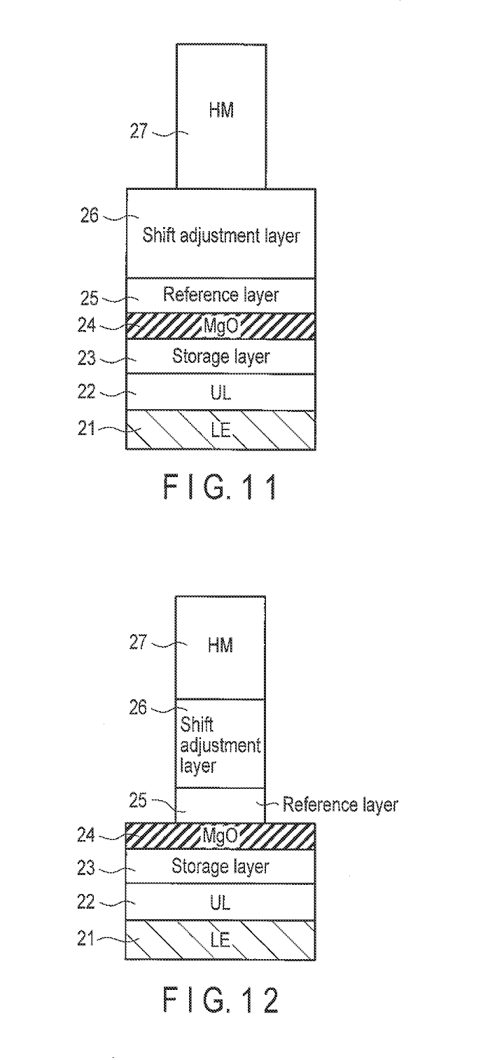

FIGS. 9 and 10 show the first example of a method of manufacturing a magnetoresistive effect element.

As shown in FIG. 9, lower layer 22, storage layer 23, tunnel barrier layer 24, reference layer 25, shift adjustment layer 26, and hard mask layer 27 are sequentially formed on lower electrode 21.

Lower layer 22 includes, e.g., (Co/Pt)ₙ. (Co/Pt)ₙ means a structure in which a Co layer and Pt layer are alternately stacked once or more.

Storage layer 23 and reference layer 25 are magnetic layers made of, e.g., CoPt or FePt having perpendicular magnetization. Tunnel barrier layer 24 is made of, e.g., MgO.

Perpendicular magnetization is a phenomenon in which the direction of remnant magnetization becomes perpendicular to or almost perpendicular to the film surfaces (upper/lower surfaces) of storage layer 23 and reference layer 25. In this specification, “almost perpendicular” means a remnant magnetization direction within the range of 45°<θ≦90° with respect to the film surfaces of storage layer 23 and reference layer 25.

Shift adjustment layer 26 has a function of adjusting a shift of the magnetic hysteresis loop of storage layer 23 arising from the structure of the magnetoresistive effect element. Shift adjustment layer 26 is made of, e.g., CoPt. An intermediate layer (e.g., Ru) may be interposed between reference layer 25 and shift adjustment layer 26.

Shift adjustment layer 26 is not an element essential to the magnetoresistive effect element and can be omitted. This is because a shift of the magnetic hysteresis loop of storage layer 23 can be adjusted without shift adjustment layer 26.

For example, reference layer 25 is made of TbCoFe/CcFeB. Adjusting the composition ratio of Tb and CoFe can set the apparent saturation magnetization (net-Ms) of reference layer 25 to 0. Adjusting the CoFe ratio to 70 to 80 at. % can cancel saturation magnetization of TbCoFe/CoFeB to 0.

Hard mask layer 27 is made of a metal such as Ta, Ti, or Al, or a nitride or oxide film of this metal.

Then, a resist pattern is formed on hard mask layer 27 by PEP (Photo Engraving Process), and hard mask layer 27 is patterned by a plasma etching using this resist pattern as a mask. This plasma etching is performed using a fluorocarbon gas containing CF₄, CHF₃, O₄F₈, C₄F₆, or the like. After that, the resist pattern is removed.

As shown in FIG. 10, shift adjustment layer 26 reference layer 25, tunnel barrier layer 24, storage layer 23, and lower layer 22 are patterned by a plasma etching using hard mask layer 27 as a mask. At this time, hard mask layer 27 is used as a mask because, if a photoresist is used as a mask, storage layer 23 and reference layer 25 may be oxidized in removing the photoresist by ashing.

This plasma etching is performed using, e.g., the etching apparatus in FIG. 1.

More specifically, Cl₂ gas is introduced into chamber 12 at a flow rate of about 200 SCCM in a state of setting the pressure in chamber 12 at about 1 Pa. A power of about 1,000 W is applied to upper electrode 13b, and a high-frequency of about 13.56 MHz and a bias power of about 400 W are applied to lower electrode 13a. Further, a microwave of about 5.7 GHz is generated using microwave generating portion 15 having a power of about 500 W, and applied to wafer (magnetoresistive effect element) 19 through waveguide 16 and lower electrode 13a.

Accordingly, wafer 19 is heated instantaneously and the temperature of wafer 19 is set within an optimum range. In a state of setting the temperature of wafer 19 within the optimum range, shift adjustment layer 26, reference layer 25, tunnel barrier layer 24, storage layer 23, and lower layer 22 are etched in about 20 sec using a Cl₂ gas plasma.

By these steps, the magnetoresistive effect element is formed. The taper angle of the magnetoresistive effect element formed by this manufacturing method was an almost right angle (90°) The saturation magnetization amount of the magnetoresistive effect element was measured by the VSM (Vibrating Sample Magnetometer) method, and it was found that the saturation magnetization amount hardly decreased.

In this fashion, the above-described manufacturing method can etch a magnetoresistive effect element (etching resistant material) at a high speed and high precision with small damage.

Note that the etching gas used to pattern the magnetoresistive effect element can be a halogen compound gas such as HCl gas or BCl₃ gas, instead of Cl₂ gas (halogen gas). Alternatively, an inert gas such as Ar gas, He gas, or Xe gas, or a gas containing an oxide (O₂) or nitride (N₂) may be mixed in the halogen gas or halogen compound gas.

The pressure in the chamber is not limited to about 1 Pa. The pressure in the chamber desirably has a value falling within the range of 0.5 Pa to 3 Pa, and more desirably a value falling within the range of 1 Pa to 2 Pa.

The bias power desirably has a value falling within the range of 300 to 600 W, and more desirably a value falling within the range of 300 to 400 W. The power applied to upper electrode 13b desirably has a value falling within the range of 200 to 4,000 W, and more desirably a value falling within the range of 500 to 1,500 W.

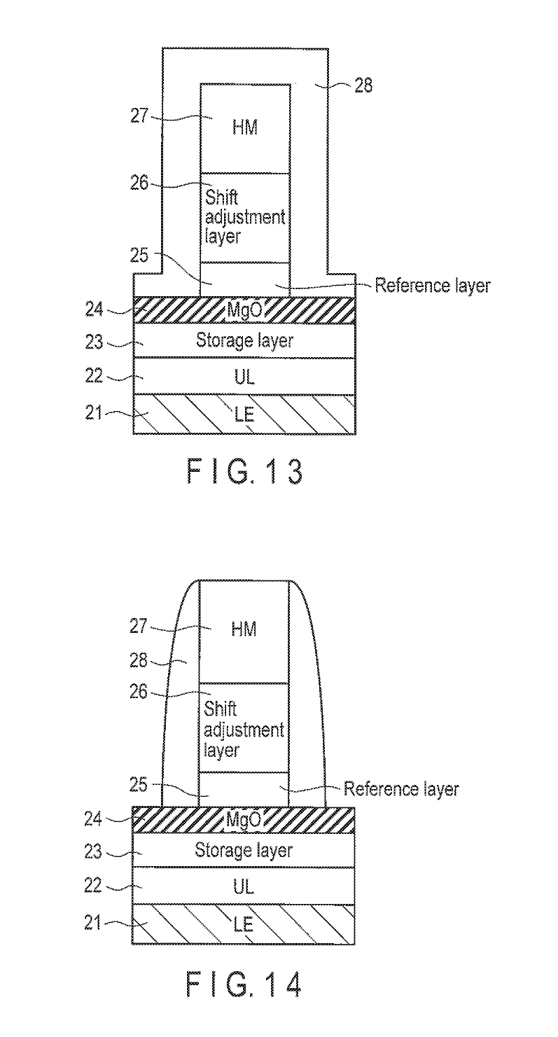

FIGS. 11, 12, 13, 14, and 15 show the second example or the method of manufacturing a magnetoresistive effect element.

Compared to the first example, the second example has a feature in a process of making the sizes of storage layer 23 and reference layer 25 different from each other. With this structure, even when a re-deposition layer is formed on the sidewalls of storage layer 23 and reference layer 25 upon etching, it does not generate an electrical short circuit between storage layer 23 and reference layer 25.

As shown in FIG. 11, lower layer 22, storage layer 23, tunnel barrier layer 24, reference layer 25, shift adjustment layer 26, and hard mask layer 27 are sequentially formed on lower electrode 21.

Lower layer 22 includes, e.g., (Co/Pt)ₙ. Storage layer 23 and reference layer 25 are magnetic layers made of, e.g., CoPt or FePt having perpendicular magnetization. Tunnel barrier layer 24 is made of, e.g., MgO.

Shift adjustment layer 26 has a function of adjusting a shift of the magnetic hysteresis loop of storage layer 23 arising from the structure of the magnetoresistive effect element. Shift adjustment layer 26 is made of, e.g., CoPt. An intermediate layer (e.g., Ru) may be interposed between reference layer 25 and shift adjustment layer 26.

Shift adjustment layer 26 is not an element essential to the magnetoresistive effect element and can be omitted. This is because a shift of the magnetic hysteresis loop of storage layer 23 can be adjusted without shift adjustment layer 26.

Hard mask layer 27 is, e.g., a metal layer.

Then, a resist pattern is formed on hard mask layer 27 by PEP, and hard mask layer 27 is patterned by a plasma etching using this resist pattern as a mask. This plasma etching is performed using a fluorocarbon gas containing CF₄, CHF₃, C₄F₈, C₄F₆, or the like. After that, the resist pattern is removed.

As shown in FIG. 12, shift adjustment layer 26 and reference layer 25 are patterned by a plasma etching using hard mask layer 27 as a mask. At this time, hard mask layer 27 is used as a mask because, if a photoresist is used as a mask, reference layer 25 may be oxidized in removing the photoresist by ashing.

This plasma etching is performed using, e.g., the etching apparatus in FIG. 1.

More specifically, Cl₂ gas is introduced into chamber 12 at a flow rate of about 200 SCCM in a state of setting the pressure in chamber 12 at about 1 Pa. A power of about 1,000 W is applied to upper electrode 13b, and a high-frequency of about 13.56 MHz and a bias power of about 400 W are applied to lower electrode 13a. Further, a microwave of about 5.7 GHz is generated using microwave generating portion 15 having a power of about 500 W, and applied to wafer (magnetoresistive effect element) 19 through waveguide 16 and lower electrode 13a.

As a result, wafer 19 is heated instantaneously and the temperature of wafer 19 is set within an optimum range. In a state of setting the temperature of wafer 19 within the optimum range, shift adjustment layer 26 and reference layer 25 are etched in about 10 sec using a Cl₂ gas plasma.

As shown in FIG. 13, sidewall spacer 28 is formed to cover reference layer 25, shift adjustment layer 26, and hard mask layer 27. Sidewall spacer 28 is made of, e.g., BN, SiC, B₄C, Al₂O₃, or AlN.

Sidewall spacer 28 is formed by thermal ALD, plasma ALD, plasma CVD, IBD, sputtering, or the like. Thereafter, sidewall spacer 28 is etched by, e.g., a plasma etching, leaving it only on the sidewalls of reference layer 25, shift adjustment layer 26, and hard mask layer 27, as shown in FIG. 14.

As shown in FIG. 15, tunnel barrier layer 24, storage layer 23, and lower layer 22 are patterned by a plasma etching using hard mask layer 27 and sidewall sparer 28 as a mask.

This plasma etching is also performed using, e.g., the etching apparatus in FIG. 1.

More specifically, Cl₂ gas is introduced into chamber 12 at a flow rate of about 200 SCCN in a state of setting the pressure in chamber 12 at about 1 Pa. A power of about 1,000 W is applied to upper electrode 13b, and a high-frequency of about 13.56 MHz and a bias power of about 400 N are applied to lower electrode 13a. Further, a microwave of about 5.7 GHz is generated using microwave generating portion 15 having a power of about 500 W, and applied to wafer (magnetoresistive effect element) 19 through waveguide 16 and lower electrode 13a.

Accordingly, wafer 19 is heated instantaneously and the temperature of wafer 19 is set within an optimum range. In a state of setting the temperature of wafer 19 within the optimum range, tunnel barrier layer 24, storage layer 23, and lower layer 22 are etched in about 10 sec using a Cl₂ gas plasma.

By these steps, the magnetoresistive effect element is formed. The taper angle of the magnetoresistive effect element formed by this manufacturing method was almost a right angle (90°). The saturation magnetization amount of the magnetoresistive effect element was measured by the VSM method, and it was found that the saturation magnetization amount hardly decreased.

Therefore, the above-described manufacturing method can etch a magnetoresistive effect element (etching resistant material) at a high speed and high precision with small damage.

Note that the etching gas used to pattern the magnetoresistive effect element can be a halogen compound gas such as HCl gas or BCl₃ gas, instead of Cl₂ gas (halogen gas). Alternatively, an inert gas such as Ar gas, He gas, or Xe gas, or a gas containing an oxide (O₂) or nitride (N₂) may be mixed in the halogen gas or halogen compound gas.

The pressure in the chamber is not limited to about 1 Pa. The pressure in the chamber desirably has a value falling within the range of 0.5 Pa to 3 Pa, and more desirably a value falling within the range of 1 Pa to 2 Pa.

The bias power desirably has a value falling within the range of 300 to 600 W, and more desirably a value falling within the range of 300 to 400 W. The power applied to upper electrode 13b desirably has a value falling within the range of 200 to 4,000 W, and more desirably a value falling within the range of 500 to 1,500 W.

### (5) APPLICATION EXAMPLE

The magnetoresistive effect element formed by the above-described semiconductor device manufacturing method is applicable to an MRAM, spin FET (Field Effect Transistor), and the like. The MRAM will be explained.

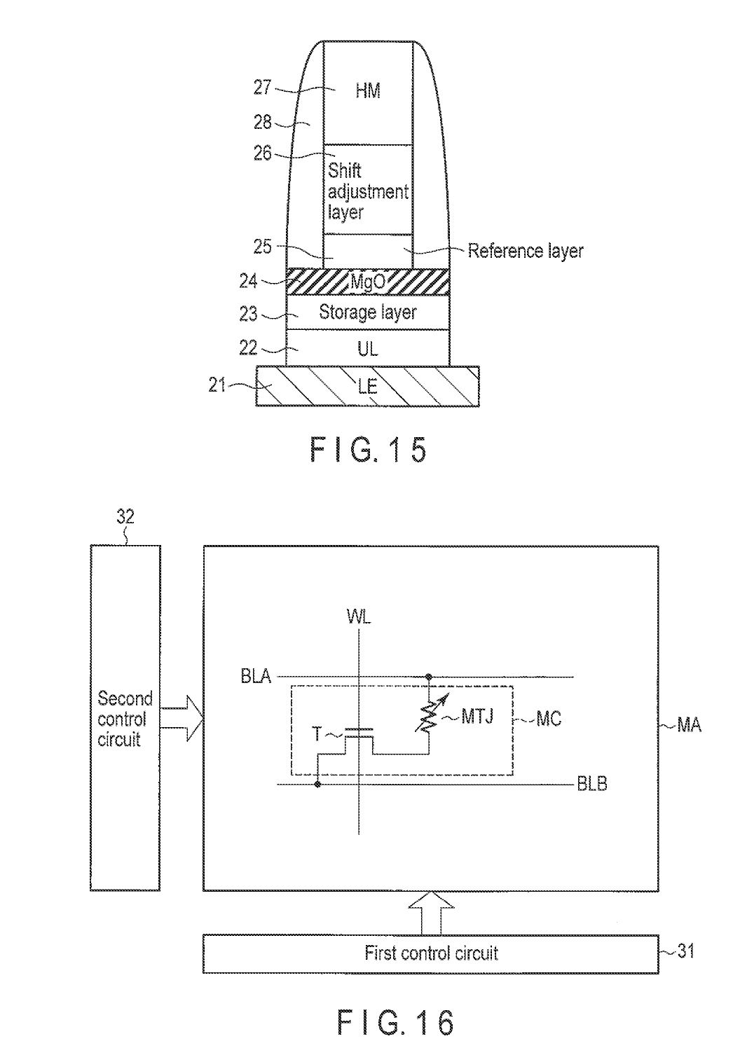

FIG. 16 shows the equivalent circuit of an MRAM memory cell.

Memory cell MC in memory cell array MA includes a series connection of magnetoresistive effect element MTJ and switching element (e.g., FET) T. The series connection has one end (one end of magnetoresistive effect element MTJ) connected to bit line BLA, and the other end (one end of switching element T) connected to hit line BLE. The control terminal of switching element T, e.g., the gate electrode of the FET is connected to word line WL.

First control circuit 31 controls the potential of word line WL. Second control circuit 32 controls the potential of bit line BLA.

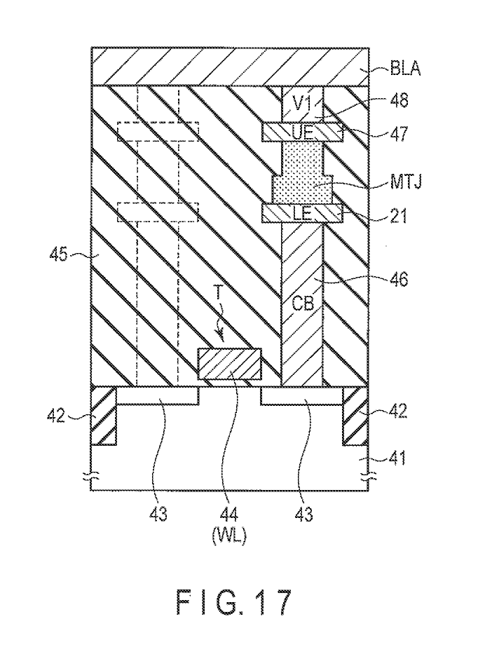

FIG. 17 shows the memory cell of the MRAM.

Semiconductor substrate 41 is, e.g., a silicon substrate, and its conductivity type is arbitrarily a p type or n type. A silicon oxide layer having an STI structure is arranged as element isolation insulating layer 42 in semiconductor substrate 41.

Switching element T is arranged in the surface region of semiconductor substrate 41, more specifically, an element region (active area) surrounded by element isolation insulating layer 42. In this example, switching element T is an FET, and includes two source/drain diffusion layers 43 in semiconductor substrate 41, and gate electrode 44 arranged in the channel region between source/drain diffusion layers 43. Gate electrode 44 functions as word line WL.

Switching element T is covered with insulating layer (e.g., silicon oxide) 45. A contact hole is formed in insulating layer 45, and contact via (CB) 46 is arranged in the contact hole. Contact via 46 is made of a metal material such as W (tungsten) or Cu (copper).

The lower surface of contact via 46 is connected to switching element T. In this example, contact via 46 directly contacts source/drain diffusion layer 43.

Lower electrode 21 is arranged on contact via 46. Lower electrode 21 has a stacked structure of, e.g., Ta (10 nm)/Ru (5 nm)/Ta (5 nm).

Magnetoresistive effect element MTJ is arranged on lower electrode 21, that is, immediately above contact via 46. Upper electrode (e.g., TiN) 47 is arranged on magnetoresistive effect element MTJ. Upper electrode 47 is connected to bit line (e.g., Cu) BLA through via (e.g., Cu) 48.

### (6) CONCLUSION

According to the embodiment, an etching resistant material can be etched at a high speed and high precision with small damage.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An etching apparatus comprising:
a stage having an upper surface and a lower surface, and being capable of mounting a substrate on the upper surface;
a chamber covering above the upper surface;
a lower electrode having an opening portion, and provided under the lower surface;
a gas supplying portion supplying an etching gas in the chamber;
a high-frequency power source portion executing a plasma gasification of the etching gas by applying a high-frequency to the lower electrode;
a micro wave generating portion setting a temperature of the substrate within an optimum range by applying a micro wave to the substrate through the opening portion; and
a control portion controlling the gas supplying portion, the high-frequency power source portion and the micro wave generating portion.

2. The apparatus of claim 1,
wherein the control portion executes an operation which sets the temperature of the substrate within the optimum range by the micro wave generating portion in parallel to an operation which supplies the etching gas in the chamber by the gas supplying portion.

3. The apparatus of claim 1,
wherein the control portion executes an operation which sets the temperature of the substrate within the optimum range by the micro wave generating portion in parallel to an operation which executes the plasma gasification of the etching gas by the high-frequency power source portion.

4. The apparatus of claim 1,
wherein the control portion sets the optimum range from 200° C. to 350° C. when the substrate includes a ferromagnetic material.

5. The apparatus of claim 1,
wherein the control portion sets the optimum range from 250° C. to 400° C. when the substrate includes a ferroelectric material.

6. The apparatus of claim 1,
wherein the stage has a round shape and the opening portion includes slits which extends from a center to an edge of the stage.

7. The apparatus of claim 1,
wherein the stage has a round shape and the opening portion includes slits which has a curvature radius to a center of the stage.

8. An etching method using the apparatus of claim 1, the method comprising:
setting the temperature of the substrate within the optimum range in parallel to supplying the etching gas in the chamber; and
etching the substrate by executing the plasma gasification.

9. An etching method using the apparatus of claim 1, the method comprising:
supplying the etching gas in the chamber;
etching the substrate by setting the temperature of the substrate within the optimum range in parallel to executing the plasma gasification.

10. An etching method using the apparatus of claim 1, the method comprising:
setting the temperature of the substrate within the optimum range;
supplying the etching gas in the chamber;
etching the substrate by executing the plasma gasification.

11. A method of manufacturing a semiconductor device, the method comprising:
forming a stacked structure including at least one of a precious metal, a ferroelectric material and a ferromagnetic material on a semiconductor substrate; and
etching the stacked structure by a plasma etching in a state of setting a temperature of the semiconductor substrate within a optimum range by a micro wave.

12. The method of claim 11,
wherein the forming the stacked structure comprises forming a tunnel barrier layer on a first ferromagnetic layer, and forming a second ferromagnetic layer on the tunnel barrier layer, and
the etching the stacked structure is executed by using a hard mask layer including a metal as a mask.

13. The method of claim 11,
wherein the etching the stacked structure executes in a state of setting the optimum range from 200° C. to 350° C. by the micro wave, when the substrate includes a ferromagnetic material.

14. The method of claim 11,
wherein the etching the stacked structure executes in a state of setting the optimum range from 250° C. to 400° C. by the micro wave, when the substrate includes a ferroelectric material.
